(19) United States
(12) Patent Application Publication
(10) Pub. No.: US 2022/0288742 A1
(43) Pub. Date: Sep. 15, 2022

(54) POLISHING APPARATUS AND POLISHING METHOD

(71) Applicant: EBARA CORPORATION, Tokyo (JP)

(72) Inventors: Nobuyuki Takahashi, Tokyo (JP); Masaki Kinoshita, Tokyo (JP)

(21) Appl. No.: 17/638,109

(22) PCT Filed: Aug. 12, 2020
(86) PCT No.: PCT/JP2020/030688

§ 371 Date: Feb. 24, 2022

(30) Foreign Application Priority Data
Aug. 29, 2019 (JP) 2019-156921

(51) Int. Cl. B24B 37/013; B24B 49/12

(52) U.S. Cl. CPC B24B 37/013; B24B 49/12

(57) ABSTRACT

The present invention relates to a polishing apparatus and a polishing method for polishing a substrate while detecting a film thickness of the substrate by analyzing reflected light from the substrate on a polishing pad. The polishing apparatus includes a polishing table (3) configured to support a polishing pad (2) having a through-hole (61); a pad-height measuring device (32) configured to measure a height of the polishing surface (2a); a pure-water supply line (63) and a pure-water suction line (64) coupled to the through-hole (61); a flow-rate adjusting device (71) coupled to the pure-water supply line (63); and an operation controller (35) configured to control an operation of the flow-rate adjusting device (71). The operation controller (35) determines a flow rate of the pure water corresponding to a measured value of the height of the polishing surface (2a) from correlation data, and controls the operation of the flow-rate adjusting device (71) such that the pure water flows through the pure-water supply line (63) at the determined flow rate.

### TECHNICAL FIELD

The present invention relates to a polishing apparatus and a polishing method for polishing a substrate, such as a wafer, on a polishing pad, and in particular relates to a polishing apparatus and a polishing method for polishing the substrate while detecting a film thickness of the substrate by analyzing reflected light from the substrate on the polishing pad.

### BACKGROUND ART

A manufacturing process for semiconductor devices includes various processes, such as polishing of an insulating film (e.g., SiO₂) and polishing of a metal film (e.g., copper or tungsten). Manufacturing processes for back-illuminated CMOS sensor and through-silicon-via (TSV) include a process of polishing a silicon layer (or a silicon wafer) in addition to processes of polishing an insulating film and a metal film.

Wafer polishing is generally performed using a chemical mechanical polishing apparatus (CMP apparatus). This CMP apparatus is configured to polish a surface of a wafer by rubbing the wafer against a polishing pad while supplying slurry onto the polishing pad attached to a polishing table. Polishing of the wafer is terminated when a thickness of a film (e.g., an insulating film, a metal film, a silicon layer, etc.) constituting the surface of the wafer reaches a predetermined target value. Therefore, the film thickness is measured during the polishing of the wafer.

An example of a film-thickness measuring device is an optical film-thickness measuring device that measures a film thickness by directing light to a surface of a wafer and analyzing optical information contained in reflected light from the wafer. This optical film-thickness measuring device includes a sensor head having a light emitting element and a light receiving element arranged in the polishing table. The polishing pad has a through-hole at the same position as the position of the sensor head. The light emitted from the sensor head is transmitted to the wafer through the through-hole of the polishing pad, and the reflected light from the wafer passes through the through-hole again and reaches the sensor head.

During the polishing of the wafer, the slurry is supplied onto the polishing pad. The slurry may flow into the through-hole and may hinder the traveling of the light. Therefore, pure water is supplied to the through-hole in order to ensure the light passage. The through-hole is filled with the pure water, and the slurry and polishing debris that have entered the through-hole are discharged together with the pure water through a drain line. The flow of pure water formed in the through-hole ensures the light passage and allows for highly accurate film thickness measurement.

### CITATION LIST

### Patent Literature

Patent document 1: Japanese laid-open patent publication No. 2006-526292

### SUMMARY OF INVENTION

### Technical Problem

The polishing pad gradually wears as wafers are polished repeatedly and the polishing pad is dressed repeatedly. As the polishing pad wears, a volume of the through-hole formed in the polishing pad decreases. As a result, the pure water overflows onto the polishing surface of the polishing pad, dilutes the slurry, and locally lowers a polishing rate of the wafer. On the other hand, if the flow rate of the pure water is too low, the slurry enters the through-hole and obstructs the passage of light. As a result, the optical film-thickness measuring device cannot measure an accurate film thickness of the wafer.

Thus, the present invention provides a polishing apparatus and a polishing method capable of preventing pure water from overflowing a through-hole of a polishing pad and preventing slurry from entering the through-hole during polishing of a substrate, such as a wafer.

### Solution to Problem

In an embodiment, there is provide a polishing apparatus for a substrate, comprising: a polishing table configured to support a polishing pad, the polishing pad having a through-hole; a polishing head configured to press the substrate against a polishing surface of the polishing pad; a pad-height measuring device configured to measure a height of the polishing surface; a pure-water supply line and a pure-water suction line coupled to the through-hole; an optical film thickness measurement system configured to direct light to the substrate through the through-hole, receive reflected light from the substrate through the through-hole, and determine a film thickness of the substrate based on the reflected light; a flow-rate adjusting device coupled to the pure-water supply line; and an operation controller configured to control an operation of the flow-rate adjusting device, the operation controller including: a memory storing a program and correlation data indicating a relationship between the height of the polishing surface and flow rate of the pure water, and an arithmetic device configured to perform an arithmetic operation according to an instruction included in the program to determine a flow rate of the pure water corresponding to a measured value of the height of the polishing surface, and control the operation of the flow-rate adjusting device such that the pure water flows through the pure-water supply line at the determined flow rate.

In an embodiment, the correlation data indicates the relationship in which the flow rate of the pure water decreases as the height of the polishing surface decreases.

In an embodiment, the flow-rate adjusting device comprises a feeding pump device, the correlation data indicates a relationship between the height of the polishing surface and rotation speed of the feeding pump device, and the arithmetic device is configured to perform the arithmetic operation according to the instruction included in the program to determine a rotation speed of the feeding pump device corresponding to the measured value of the height of the polishing surface, and set operation of the feeding pump device such that the feeding pump device rotates at the determined rotation speed.

In an embodiment, the flow-rate adjusting device comprises a flow-rate control valve, and the arithmetic device is configured to perform the arithmetic operation according to the instruction included in the program to determine a flow rate of the pure water corresponding to the measured value of the height of the polishing surface, and set operation of the flow-rate control valve such that the pure water flows through the pure-water supply line at the determined flow rate.

In an embodiment, the polishing apparatus further comprises: an outflow-side pump coupled to the pure-water suction line; and a frequency variable device configured to control a rotation speed of the outflow-side pump.

In an embodiment, there is provided a polishing apparatus for a substrate, comprising: a polishing table configured to support a polishing pad, the polishing pad having a through-hole; a polishing head configured to press the substrate against a polishing surface of the polishing pad; a pad-height measuring device configured to measure a height of the polishing surface; a pure-water supply line and a pure-water suction line coupled to the through-hole; an optical film thickness measurement system configured to direct light to the substrate through the through-hole, receive reflected light from the substrate through the through-hole, and determine a film thickness of the substrate based on the reflected light; a pressure adjusting device coupled to the pure-water supply line; and an operation controller configured to control an operation of the pressure adjusting device, the operation controller including: a memory storing a program and correlation data indicating a relationship between the height of the polishing surface and pressure of the pure water, and an arithmetic device configured to perform an arithmetic operation according to an instruction included in the program to determine a pressure of the pure water corresponding to a measured value of the height of the polishing surface, and control the operation of the pressure adjusting device such that the pure water having the determined pressure flows through the pure-water supply line.

In an embodiment, the correlation data indicates the relationship in which the pressure of the pure water decreases as the height of the polishing surface decreases.

In an embodiment, the pressure adjusting device comprises a feeding pump device, the correlation data indicates a relationship between the height of the polishing surface and rotation speed of the feeding pump device, and the arithmetic device is configured to perform the arithmetic operation according to the instruction included in the program to determine a rotation speed of the feeding pump device corresponding to the measured value of the height of the polishing surface, and set operation of the feeding pump device such that the feeding pump device rotates at the determined rotation speed.

In an embodiment, the pressure adjusting device comprises a pressure control valve, and the arithmetic device is configured to perform the arithmetic operation according to the instruction included in the program to determine a pressure of the pure water corresponding to the measured value of the height of the polishing surface, and set operation of the pressure control valve such that the pure water having the determined pressure flows through the pure-water supply line.

In an embodiment, the polishing apparatus further comprises: an outflow-side pump coupled to the pure-water suction line and; a frequency variable device configured to control a rotation speed of the outflow-side pump.

In an embodiment, there is provided a polishing method for a substrate, comprising: measuring a height of a polishing surface of a polishing pad, the polishing pad having a through-hole; determine, from correlation data, a flow rate of pure water corresponding to a measured value of the height of the polishing surface, the correlation data indicating a relationship between the height of the polishing surface and flow rate of the pure water; pressing the substrate against the polishing surface of the polishing pad to polish the substrate while supplying slurry onto the polishing surface; directing light from an optical film-thickness measuring system to the substrate through the through-hole and receiving reflected light from the substrate through the through-hole by the optical film-thickness measuring system, while supplying the pure water into the through-hole at the determined flow rate and sucking the pure water from the through-hole; and determining a film thickness of the substrate based on the reflected light by the optical film-thickness measuring system.

In an embodiment, the correlation data indicates the relationship in which the flow rate of the pure water decreases as the height of the polishing surface decreases.

In an embodiment, the determined flow rate of the pure water is such that the through-hole is filled with the pure water and the pure water does not overflow onto the polishing surface.

In an embodiment, there is provided a polishing method for a substrate, comprising: measuring a height of a polishing surface of a polishing pad, the polishing pad having a through-hole; determine, from correlation data, a pressure of pure water corresponding to a measured value of the height of the polishing surface, the correlation data indicating a relationship between the height of the polishing surface and pressure of the pure water; pressing the substrate against the polishing surface of the polishing pad to polish the substrate while supplying slurry onto the polishing surface; directing light from an optical film-thickness measuring system to the substrate through the through-hole and receiving reflected light from the substrate through the through-hole by the optical film-thickness measuring system, while supplying the pure water having the determined pressure into the through-hole and sucking the pure water from the through-hole; and determining a film thickness of the substrate based on the reflected light by the optical film-thickness measuring system.

In an embodiment, the correlation data indicates the relationship in which the pressure of the pure water decreases as the height of the polishing surface decreases.

In an embodiment, the determined pressure of the pure water is such that the through-hole is filled with the pure water and the pure water does not overflow onto the polishing surface.

### Advantageous Effects of Invention

The volume of the through-hole of the polishing pad varies depending on the thickness of the polishing pad. The flow rate or pressure of the pure water to be supplied to the through-hole is changed based on the change in the thickness of the polishing pad. Such an operation can prevent the pure water from overflowing the through-hole of the polishing pad and can prevent the slurry from entering the through-hole during polishing of a substrate, such as a wafer.

### BRIEF DESCRIPTION OF DRAWINGS

FIG. 1 is a schematic view showing an embodiment of a polishing apparatus;

FIG. 2 is a diagram showing an example of correlation data indicating a relationship between height of polishing surface and flow rate of pure water;

FIG. 3 is a diagram showing an example of correlation data indicating a relationship between height of polishing surface and rotation speed of feeding pump device;

FIG. 4 is a flowchart illustrating operations of the polishing apparatus shown in FIG. 1;

FIG. 5 is a schematic diagram showing another embodiment of the polishing apparatus;

FIG. 6 is a flowchart illustrating operations of the polishing apparatus shown in FIG. 5;

FIG. 7 is a schematic view showing another embodiment of the polishing apparatus;

FIG. 8 is a diagram showing an example of correlation data indicating a relationship between height of polishing surface and pressure of pure water;

FIG. 9 is a diagram showing an example of correlation data indicating a relationship between height of polishing surface and rotation speed of feeding pump device;

FIG. 10 is a flowchart illustrating operations of the polishing apparatus shown in FIG. 7;

FIG. 11 is a schematic diagram showing another embodiment of the polishing apparatus; and

FIG. 12 is a flowchart illustrating operations of the polishing apparatus shown in FIG. 11.

### DESCRIPTION OF EMBODIMENTS

Hereinafter, embodiments of the present invention will be described with reference to the drawings.

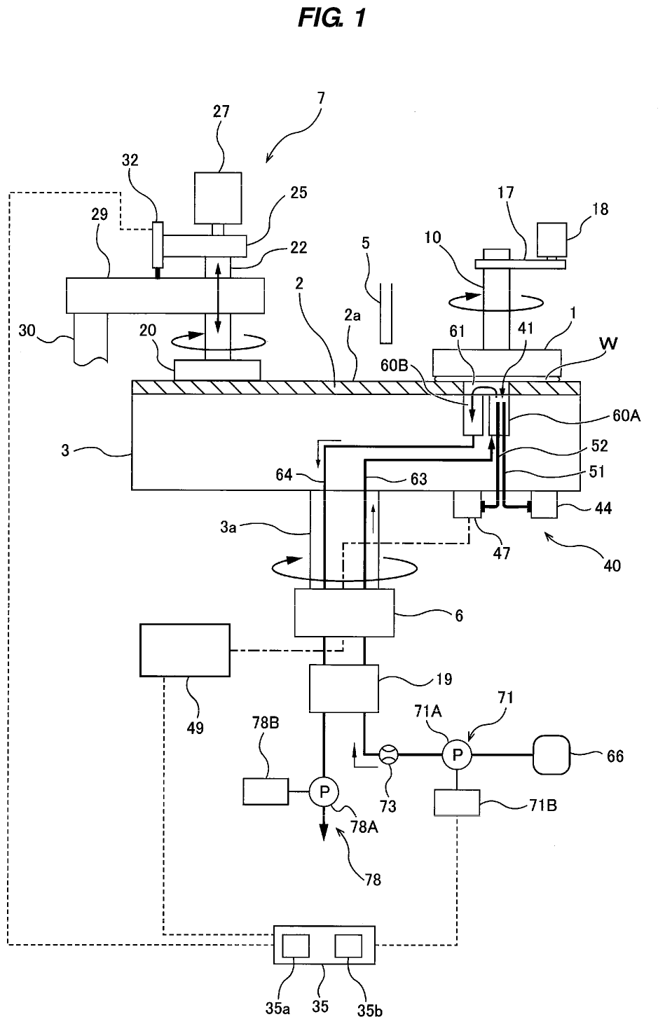

FIG. 1 is a schematic diagram showing an embodiment of a polishing apparatus. As shown in FIG. 1, the polishing apparatus includes a polishing table 3 that supports a polishing pad 2, a polishing head 1 configured to press a wafer W, which is an example of a substrate, against the polishing pad 2, a table motor 6 configured to rotate the polishing table 3, a slurry supply nozzle 5 configured to supply slurry onto the polishing pad 2, and a dressing unit 7 configured to perform dressing (conditioning) of a polishing surface 2a of the polishing pad 2.

The polishing head 1 is coupled to a head shaft 10, and the polishing head 1 is rotatable together with the head shaft 10. The head shaft 10 is coupled to a polishing-head motor 18 via a coupling device 17, such as a belt, so that the head shaft 10 is rotated by the polishing-head motor 18. The rotation of the head shaft 10 causes the polishing head 1 to rotate in a direction indicated by arrow. A table shaft 3a of the polishing table 3 is coupled to the table motor 6, and the table motor 6 is configured to rotate the polishing table 3 and the polishing pad 2 in a direction indicated by arrows.

The dressing unit 7 includes a dresser 20 configured to be brought into contact with the polishing surface 2a of the polishing pad 2, a dresser shaft 22 coupled to the dresser 20, a support block 25 that rotatably supports an upper end of the dresser shaft 22, an air cylinder 27 as a pressing-force generating device coupled to the support block 25, a dresser arm 29 that rotatably supports the dresser shaft 22, and a support shaft 30 that supports the dresser arm 29. The dresser 20 has a lower surface that constitutes a dressing surface to which abrasive grains, such as diamond particles, are fixed.

The dresser shaft 22 and the dresser 20 can move up and down relative to the dresser arm 29. The air cylinder 27 is a device that generates a force applied from the dresser 20 to the polishing pad 2. The dresser shaft 22 is rotated by a dresser motor (not shown) installed in the dresser arm 29, and the rotation of the dresser shaft 22 causes the dresser 20 to rotate about its axis. The air cylinder 27 presses the dresser 20 via the dresser shaft 22 against the polishing surface 2a of the polishing pad 2 with a predetermined force. The lower surface of the dresser 20 constituting the dressing surface is placed in sliding contact with the polishing surface 2a of the polishing pad 2 to dress (condition) the polishing surface 2a. During dressing of the polishing surface 2a, pure water is supplied from a nozzle (not shown) onto the polishing surface 2a.

The dressing unit 7 includes a pad-height measuring device 32 configured to measure a height of the polishing surface 2a. The pad-height measuring device 32 used in this embodiment is a contact-type displacement sensor. The pad-height measuring device 32 is fixed to the support block 25, and a contact element of the pad-height measuring device 32 is in contact with the dresser arm 29. Since the support block 25 can move up and down together with the dresser shaft 22 and the dresser 20, the pad-height measuring device 32 can move up and down together with the dresser shaft 22 and the dresser 20. On the other hand, the position of the dresser arm 29 in the vertical direction is fixed. The pad-height measuring device 32 moves up and down together with the dresser shaft 22 and the dresser 20 while the contact element of the pad-height measuring device 32 is in contact with the dresser arm 29. Therefore, the pad-height measuring device 32 can measure the displacement of the dresser 20 with respect to the dresser arm 29.

The pad-height measuring device 32 can measure the height of the polishing surface 2a via the dresser 20. Specifically, since the pad-height measuring device 32 is coupled to the dresser 20 via the dresser shaft 22, the pad-height measuring device 32 can measure the height of the polishing surface 2a during the dressing of the polishing pad 2. The height of the polishing surface 2a is a distance from a preset reference plane to the lower surface of the dresser 20. The reference plane is an imaginary plane. For example, if the reference plane is an upper surface of the polishing table 3, the height of the polishing surface 2a corresponds to the thickness of the polishing pad 2.

In the present embodiment, a linear scale type sensor is used as the pad-height measuring device 32, while in one embodiment, the pad-height measuring device 32 may be a non-contact type sensor, such as a laser type sensor, an ultrasonic sensor, or an eddy current sensor. Further, in one embodiment, the pad-height measuring device 32 may be fixed to the dresser arm 29 and arranged to measure a displacement of the support block 25. In this case also, the pad-height measuring device 32 can measure the displacement of the dresser 20 with respect to the dresser arm 29.

In the above-described embodiment, the pad-height measuring device 32 is configured to indirectly measure the height of the polishing surface 2a based on the position of the dresser 20 when the dresser 20 is in contact with the polishing surface 2a.

The configuration of the pad-height measuring device 32 is not limited to this embodiment as long as the pad-height measuring device 32 can measure the height of the surface 2a accurately. In one embodiment, the pad-height measuring device 32 may be a non-contact sensor, such as a laser sensor or an ultrasonic sensor, which is arranged above the polishing pad 2 and directly measures the height of the polishing surface 2a. The polishing apparatus includes an operation controller 35, and the pad-height measuring device 32 is coupled to the operation controller 35. An output signal of the pad-height measuring device 32 (i.e., a measured value of the height of the polishing surface 2a) is sent to the operation controller 35. The operation controller 35 is composed of at least one computer.

The polishing apparatus includes an optical film-thickness measuring system 40 configured to measure a film thickness of the wafer W. The optical film-thickness measuring system 40 includes an optical sensor head 41, a light source 44, a spectrometer 47, and a data processor 49. The optical sensor head 41, the light source 44, and the spectrometer 47 are attached to the polishing table 3 and rotate together with the polishing table 3 and the polishing pad 2. A position of the optical sensor head 41 is such that the optical sensor head 41 sweeps across the surface of the wafer W on the polishing pad 2 each time the polishing table 3 and the polishing pad 2 make one rotation. The optical sensor head 41 is coupled to the light source 44 and the spectrometer 47, and the spectrometer 47 is coupled to the data processor 49.

The light source 44 transmits the light to the optical sensor head 41, and the optical sensor head 41 emits the light toward the wafer W. Reflected light from the wafer W is received by the optical sensor head 41 and transmitted to the spectrometer 47.

The spectrometer 47 decomposes the reflected light according to wavelengths and measures an intensity of the reflected light at each of wavelengths. The spectrometer 47 sends measurement data of the intensities of the reflected light to the data processor 49. The data processor 49 generates a spectrum of the reflected light from the measurement data of the intensities of the reflected light. This spectrum indicates a relationship between the intensity and the wavelength of the reflected light, and a shape of the spectrum changes according to the film thickness of the wafer W. The data processor 49 determines the film thickness of the wafer W from the spectrum.

The wafer W is polished as follows. While the polishing table 3 and the polishing head 1 are rotating in the directions indicated by the arrows in FIG. 1, the slurry is supplied from the slurry supply nozzle 5 onto the polishing surface 2a of the polishing pad 2 on the polishing table 3. The dresser 20 is located apart from the polishing pad 2. While the wafer W is rotated by the polishing head 1, the wafer W is pressed by the polishing head 1 against the polishing surface 2a of the polishing pad 2 in the presence of slurry on the polishing pad 2. The surface of the wafer W is polished by a chemical action of the slurry and a mechanical action of the abrasive grains contained in the slurry.

During the polishing of the wafer W, the optical sensor head 41 irradiates a plurality of measurement points on the wafer W with the light and receives the reflected light from the wafer W while moving across the surface of the wafer W on the polishing pad 2 each time the polishing table 3 makes one rotation. The data processor 49 determines the film thickness of the wafer W from the measurement data of the intensity of the reflected light.

After the polishing of the wafer W is terminated, the wafer W is separated from the polishing pad 2 and transferred to a next process. Thereafter, dressing of the polishing surface 2a of the polishing pad 2 is performed by the dresser 20. Specifically, pure water is supplied to the polishing surface 2a from a pure water nozzle (not shown) while the polishing pad 2 and the polishing table 3 are rotating. The dresser 20 is placed in sliding contact with the polishing surface 2a of the polishing pad 2 while the dresser 20 is rotating. The dresser 20 regenerates (dresses) the polishing surface 2a by slightly scraping off the polishing pad 2. During dressing of the polishing pad 2, the pad-height measuring device 32 measures the height of the polishing surface 2a.

Hereinafter, details of the optical film-thickness measuring system 40 will be described. The optical film-thickness measuring system 40 includes a light-emitting optical fiber cable 51 configured to direct the light, emitted by the light source 44, to the surface of the wafer W, and a light-receiving optical fiber cable 51 configured to receive the reflected light from the wafer W and transmit the reflected light to the spectrometer 47. A distal end of the light-emitting optical fiber cable 51 and a distal end of the light-receiving optical fiber cable 52 are located in the polishing table 3. The distal end of the light-emitting optical fiber cable 51 and the distal end of the light-receiving optical fiber cable 52 constitute the optical sensor head 41 that directs the light to the surface of the wafer W and receives the reflected light from the wafer W. The other end of the light-emitting optical fiber cable 51 is coupled to the light source 44, and the other end of the light-receiving optical fiber cable 52 is coupled to the spectrometer 47. The spectrometer 47 is configured to decompose the reflected light from the wafer W according to the wavelengths and measure the intensities of the reflected light over a predetermined wavelength range.

The polishing table 3 has a first hole 60A and a second hole 60B that are open in the upper surface of the polishing table 3. Further, the polishing pad 2 has a through-hole 61 formed at a position corresponding to these holes 60A and 60B. The holes 60A and 60B communicate with the through-hole 61, and the through-hole 61 is open in the polishing surface 2a. The first hole 60A is coupled to a pure-water supply line 63, and the second hole 60B is coupled to a pure-water suction line 64. The optical sensor head 41, which is composed of the distal end of the light-emitting optical fiber cable 51 and the distal end of the light-receiving optical fiber cable 52, is arranged in the first hole 60A and is located below the through-hole 61.

The light source 44 may be a pulse light source, such as a xenon flash lamp. The light-emitting optical fiber cable 51 is a light transmission element configured to transmit the light emitted by the light source 44 to the surface of the wafer W. The distal ends of the light-emitting optical fiber cable 51 and the light-receiving optical fiber cable 52 are located in the first hole 60A and are located close to the surface, to be polished, of the wafer W. The optical sensor head 41, which is composed of the distal ends of the light-emitting optical fiber cable 51 and the light-receiving optical fiber cable 52, is arranged so as to face the wafer W held by the polishing head 1. Each time the polishing table 3 rotates, the light is applied to a plurality of measurement points of the wafer W. In the present embodiment, only one optical sensor head 41 is provided, but a plurality of optical sensor heads 41 may be provided.

During polishing of the wafer W, the light is directed from the optical sensor head 41 to the wafer W through the through-hole 61, and the reflected light from the wafer W is received by the optical sensor head 41 through the through-hole 61. The spectrometer 47 measures the intensity of the reflected light at each of the wavelengths over a predetermined wavelength range, and sends the obtained measurement data to the data processor 49. This measurement data is a film-thickness signal that changes according to the film thickness of the wafer W. The data processor 49 generates, from the measurement data, a spectrum representing the light intensities at respective wavelengths, and further determines the film thickness of the wafer W from the spectrum. A known method is used for determining the film thickness of the wafer W from the spectrum of the reflected light.

During polishing of the wafer W, the pure water is supplied through the pure-water supply line 63 into the first hole 60A and the through-hole 61 to fill the first hole 60A and the through-hole 61. The pure water further flows from the through-hole 61 into the second hole 60B and is discharged through the pure-water suction line 64. The slurry is discharged together with the pure water, whereby an optical passage is ensured.

The pure-water supply line 63 and the pure-water suction line 64 are coupled to a rotary joint 19, which is coupled to the polishing table 3. The pure-water supply line 63 and the pure-water suction line 64 extend in the polishing table 3. One end of the pure-water supply line 63 is coupled to the first hole 60A. The other end of the pure-water supply line 63 is coupled to a pure-water supply source 66. The pure-water supply source 66 may be a utility supply source provided in a factory where the polishing apparatus is installed.

The polishing apparatus includes a feeding pump device 71 and a flow-rate measuring device 73 which are coupled to the pure-water supply line 63. The feeding pump device 71 is a variable-speed pump device, and serves as a flow-rate adjusting device for adjusting a flow rate of the liquid flowing through the pure-water supply line 63. The feeding pump device 71 and the flow-rate measuring device 73 are located at a stationary-side of the rotary joint 19 and are arranged outside the polishing table 3. The flow-rate measuring device 73 is arranged between the rotary joint 19 and the feeding pump device 71.

The feeding pump device 71, which is the flow-rate adjusting device, includes an inflow-side pump 71A and an inflow-side frequency variable device 71B. The inflow-side frequency variable device 71B is configured to control a rotation speed of the inflow-side pump 71A. The inflow-side frequency variable device 71B is a variable frequency amplifier configured to be able to change a frequency of a voltage applied to a motor (not shown) of the inflow-side pump 71A. In one embodiment, the inflow-side frequency variable device 71B may be an inverter. The inflow-side frequency variable device 71B is electrically coupled to the operation controller 35, and the operation of the feeding pump device 71 is controlled by the operation controller 35.

The feeding pump device 71 is configured to pressurize the pure water delivered from the pure-water supply source 66 through the pure-water supply line 63. The pressurized pure water is supplied to the first hole 60A through the pure-water supply line 63, and is further supplied to the through-hole 61 from the first hole 60A. The flow rate of the pure water to be supplied to the through-hole 61, i.e., the flow rate of the pure water flowing through the pure-water supply line 63, is measured by the flow-rate measuring device 73. The flow rate of the pure water to be supplied to the through-hole 61 through the pure-water supply line 63 during polishing of the wafer W is uniquely defined by the rotation speed of the feeding pump device 71.

One end of the pure-water suction line 64 is coupled to the second hole 60B. The pure-water suction line 64 is coupled to a drain pump device 78 for sucking the pure water from the through-hole 61. The drain pump device 78 is installed outside the polishing table 3. The drain pump device 78 includes an outflow-side pump 78A and an outflow-side frequency variable device 78B. The outflow-side pump 78A is coupled to the pure-water suction line 64, and the outflow-side frequency variable device 78B is configured to control a rotation speed of the outflow-side pump 78A. The outflow-side frequency variable device 78B is a variable frequency amplifier configured to be able to change a frequency of a voltage applied to a motor (not shown) of the outflow-side pump 78A. In one embodiment, the outflow-side frequency variable device 78B may be an inverter.

The pure water is delivered through the pure-water supply line 63 by the feeding pump device 71 and is supplied to the through-hole 61. The pure water flows from the through-hole 61 into the second hole 60B, and is sucked by the drain pump device 78 through the pure-water suction line 64. The pure water is discharged from the drain pump device 78 to the outside of the polishing table 3. As described above, during the polishing of the wafer, the flow of the pure water is formed in the through-hole 61, and therefore the through-hole 61 serves as a pool of the pure water.

In the present embodiment, the feeding pump device 71 and the flow-rate measuring device 73 are located at the stationary-side of the rotary joint 19 and are arranged outside the polishing table 3, while in one embodiment, the feeding pump device 71 and the flow-rate measuring device 73 may be located at the rotary-side of the rotary joint 19 and may be fixed to the polishing table 3. Further, in the present embodiment, the drain pump device 78 is located at the stationary-side of the rotary joint 19 and is arranged outside the polishing table 3, while in one embodiment, the drain pump device 78 may be located at the rotary-side of the rotary joint 19 and may be fixed to the polishing table 3. Further, in one embodiment, the pure-water suction line 64 may be coupled to an outer peripheral surface of the polishing table 3 without passing through the rotary joint 19, and the pure water, sucked by the drain pump device 78 arranged in the polishing table 3, may be discharged to a slurry receiver (not shown) arranged around the polishing table 3.

The polishing pad 2 gradually wears as wafers are polished repeatedly and the polishing pad 2 is dressed repeatedly. As the polishing pad 2 wears, a volume of the through-hole 61 formed in the polishing pad 2 decreases. As a result, the pure water may overflow the through-hole 61 onto the polishing surface 2a of the polishing pad 2, may dilute the slurry, and may locally lower a polishing rate of the wafer. On the other hand, if the flow rate of the pure water is too low, the slurry enters the through-hole 61 and lowers the measuring accuracy of the optical film-thickness measuring system 40.

Thus, in the present embodiment, the flow rate of the pure water to be supplied to the through-hole 61 is adjusted by the feeding pump device 71, which is a flow-rate adjusting device, based on the height of the polishing surface 2a. Specifically, as the height of the polishing surface 2a decreases, the flow rate of the pure water to be supplied to the through-hole 61 is lowered by the feeding pump device 71. The pad-height measuring device 32 measures the height of the polishing surface 2a of the polishing pad 2 and transmits the measured value of the height of the polishing surface 2a to the operation controller 35.

The operation controller 35 includes a memory 35a storing therein a program and a correlation data indicating a relationship between the height of the polishing surface 2a and the flow rate of the pure water. The operation controller 35 further includes an arithmetic device 35b configured to perform arithmetic operations according to instructions contained in the program to determine a flow rate of the pure water corresponding to a measured value of the height of the polishing surface 2a and control the operation of the feeding pump device (flow-rate adjusting device) 71 so as to allow the pure water to flow through the pure-water supply line 63 at the determined flow rate.

The memory 35a includes a main memory to which the arithmetic device 35b is accessible, and an auxiliary memory storing the program and the correlation data therein. The main memory is, for example, a random-access memory (RAM), and the auxiliary memory is a storage device, such as a hard disk drive (HDD) or a solid state drive (SSD). The arithmetic device 35b is composed of a CPU (central processing unit), a GPU (graphic processing unit), or the like. The operation controller 35 including the memory 35a and the arithmetic device 35b is composed of at least one computer.

The purpose of supplying the pure water to the through-hole 61 during polishing of the wafer is to prevent the slurry, supplied to the polishing surface 2a, from entering the through-hole 61. When the flow rate of the pure water is too high, the pure water can prevent the slurry from entering the through-hole 61, but the pure water overflows the through-hole 61 and dilutes the slurry. On the other hand, if the flow rate of the pure water is too low, the through-hole 61 is not filled with the pure water, and the pure water cannot prevent the slurry from entering the through-hole 61. From this point of view, during polishing of the wafer, particularly when the through-hole 61 is covered with the wafer, the flow rate of the pure water is such that the through-hole 61 is filled with the pure water and the pure water does not overflow onto the polishing surface 2a.

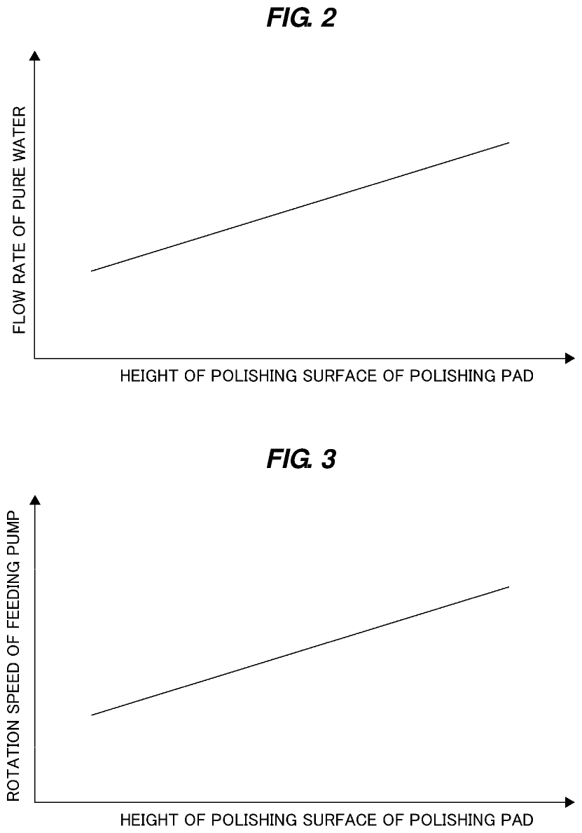

FIG. 2 is a diagram showing an example of correlation data indicating a relationship between the height of the polishing surface 2a and the flow rate of the pure water. The correlation data indicates the relationship in which the flow rate of the pure water decreases as the height of the polishing surface 2a decreases. The flow rate of the pure water corresponding to each height of the polishing pad 2 is such that the pure water fills the through-hole 61 and does not overflow onto the polishing surface 2a. Such correlation data is obtained in advance by experiments. The correlation data may be a function of the flow rate having the height of the polishing surface 2a as a variable as shown in FIG. 2, or a table showing a relationship between multiple numerical values of the height of the polishing surface 2a and multiple numerical values of the flow rate of the pure water.

The flow rate of the pure water included in the correlation data may be a physical quantity that directly indicates the flow rate of the pure water, or may be a numerical value that indirectly indicates the flow rate of the pure water. For example, the flow rate of the pure water flowing through the pure-water supply line 63 to the through-hole 61 during polishing of the wafer changes depending on the rotation speed of the feeding pump device 71. Therefore, the flow rate of the pure water included in the correlation data may be represented by the rotation speed of the feeding pump device 71. Alternatively, the flow rate of the pure water included in the correlation data may be another numerical value that indirectly indicates the flow rate of the pure water.

FIG. 3 is a diagram showing an example of the correlation data indicating the relationship between the height of the polishing surface 2a and the rotation speed of the feeding pump device 71. In this embodiment, the correlation data shown in FIG. 3 is used. This correlation data is stored in the memory 35a of the operation controller 35. The correlation data shown in FIG. 3 is data in which the flow rate of the pure water shown in FIG. 2 is replaced with the rotation speed of the feeding pump device 71.

The operation controller 35 receives the measured value of the height of the polishing surface 2a from the pad-height measuring device 32, and determines the rotation speed of the feeding pump device 71 (i.e., the flow rate of the pure water) corresponding to the measured value of the height of the polishing surface 2a from the correlation data. Further, the operation controller 35 sets the operation of the feeding pump device 71 such that the feeding pump device 71 rotates at the determined rotation speed. More specifically, the operation controller 35 sends a command signal indicating the determined rotation speed to the inflow-side frequency variable device 71B, and the inflow-side frequency variable device 71B rotates the inflow-side pump 71A at the determined rotation speed. The pure water flows through the pure-water supply line 63 at a flow rate corresponding to the height of the polishing surface 2a and flows into the through-hole 61. While the pure water is supplied to the through-hole 61, the drain pump device 78 is operated at a preset rotation speed. The pure water flows from the through-hole 61 to the second hole 60B, and further flows through the pure-water suction line 64 and is sucked by the drain pump device 78.

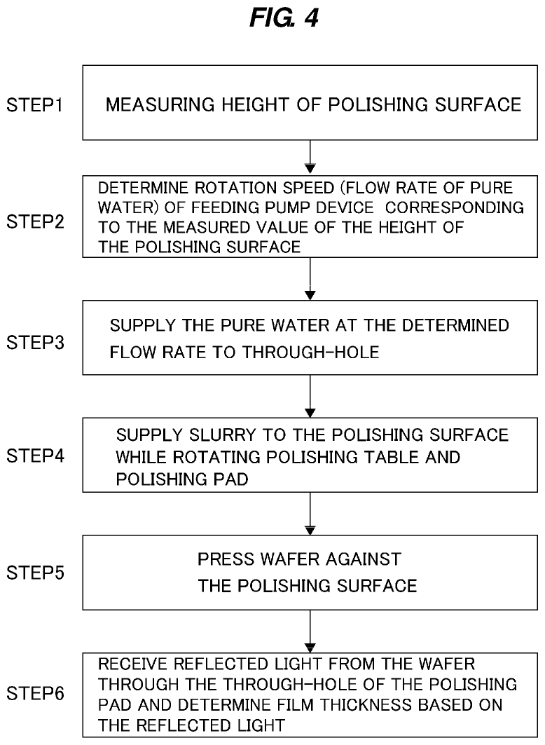

FIG. 4 is a flowchart illustrating the operation of the polishing apparatus shown in FIG. 1.

In step 1, the pad-height measuring device 32 measures the height of the polishing surface 2a while the dresser 20 dresses the polishing surface 2a of the polishing pad 2.

In step 2, the operation controller 35 determines from the correlation data the rotation speed of the feeding pump device 71 (i.e., the flow rate of the pure water) corresponding to the measured value of the height of the polishing surface 2a.

In step 3, the operation controller 35 instructs the feeding pump device 71 to operate at the rotation speed determined in the step 2 to thereby supply the pure water to the through-hole 61 through the pure-water supply line 63. Further, the pure water that has been supplied to the through-hole 61 is sucked by the drain pump device 78.

In step 4, the slurry is supplied from the slurry supply nozzle 5 to the polishing surface 2a while the polishing table 3 and the polishing pad 2 are rotated.

In step 5, the polishing head 1 presses the wafer W against the polishing surface 2a while the polishing head 1 rotates the wafer W. The surface of the wafer W is polished by the chemical action of the slurry and the mechanical action of the abrasive grains contained in the slurry. While the wafer W is pressed against the polishing surface 2a, the feeding pump device 71 operates at the rotation speed determined in the step 2.

In step 6, the optical film-thickness measuring system transmits the light to the surface of the wafer W on the polishing surface 2a through the through-hole 61, and receives the reflected light from the wafer W through the through-hole 61. During polishing of the wafer W, the optical film-thickness measuring system determines the film thickness of the wafer W based on the reflected light. The polishing end point of the wafer W is determined based on the film thickness of the wafer W.

According to the embodiment, the flow rate of the pure water to be supplied to the through-hole 61 is changed based on the change in the thickness of the polishing pad 2. Such operation can prevent the pure water from overflowing the through-hole 61 of the polishing pad 2 during polishing of the wafer W, and can fill the through-hole 61 with the pure water. As a result, the slurry is prevented from entering the through-hole 61, and the optical film-thickness measuring system 40 can accurately measure the film thickness of the wafer W.

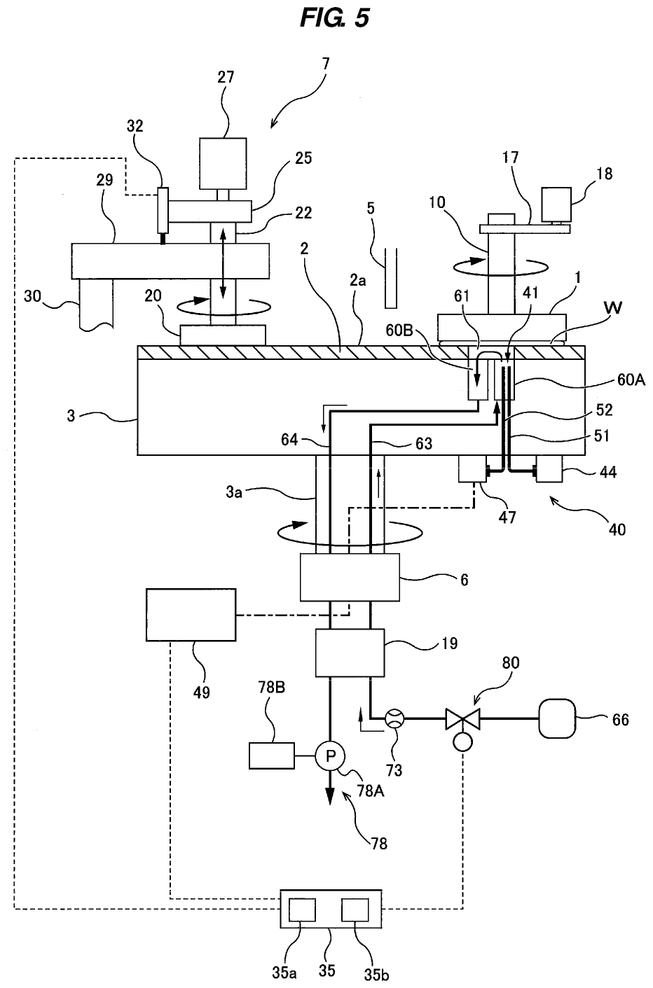

FIG. 5 is a schematic view showing another embodiment of the polishing apparatus. Configurations and operations of the present embodiment, which will not be particularly described, are the same as those of the embodiments described with reference to FIGS. 1 to 4, and therefore the repetitive descriptions thereof will be omitted. In the present embodiment, a flow-rate control valve 80 is provided, instead of the feeding pump device 71, as the flow-rate adjusting device. The arrangement of the flow-rate control valve 80 is the same as that of the feeding pump device 71 shown in FIG. 1. The configuration of this embodiment is suitable when the pressure of the pure water supplied from the pure-water supply source 66 is high to some extent.

A correlation data stored in the memory 35a is the correlation data shown in FIG. 2 indicating the relationship between the height of the polishing surface 2a and the flow rate of the pure water. The arithmetic device 35b is configured to perform the arithmetic operations according to the instruction included in the program to determine the flow rate of the pure water corresponding to the measured value of the height of the polishing surface 2a, and control the operation of the flow-rate control valve 80 so as to allow the pure water to flow through the pure-water supply line 63 at the determined flow rate.

More specifically, the operation controller 35 receives the measured value of the height of the polishing surface 2a from the pad-height measuring device 32, and determines the flow rate of the pure water corresponding to the measured value of the height of the polishing surface 2a from the correlation data. Further, the operation controller 35 sets the operation of the flow-rate control valve 80 so that the pure water flows through the pure-water supply line 63 at the above-determined flow rate. More specifically, the operation controller 35 sends a command signal indicating the determined flow rate to the flow-rate control valve 80, and the flow-rate control valve 80 operates according to the command signal. The pure water flows through the pure-water supply line 63 at the determined flow rate and flows into the through-hole 61. While the pure water is supplied to the through-hole 61, the drain pump device 78 is operated at a preset rotation speed. The pure water flows from the through-hole 61 to the second hole 60B, and further flows through the pure-water suction line 64 and is sucked by the drain pump device 78.

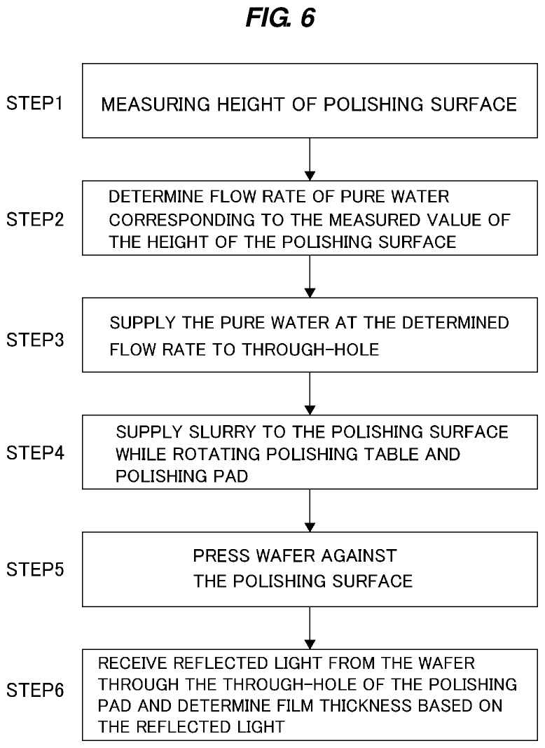

FIG. 6 is a flowchart illustrating the operation of the polishing apparatus shown in FIG. 5.

In step 1, the pad-height measuring device 32 measures the height of the polishing surface 2a while the dresser 20 dresses the polishing surface 2a of the polishing pad 2.

In step 2, the operation controller 35 determines from the correlation data the flow rate of the pure water corresponding to the measured value of the height of the polishing surface 2a.

In step 3, the operation controller 35 instructs the flow-rate control valve 80 to allow the pure water to flow at the flow rate determined in the step 2. The pure water flows through the flow-rate control valve 80 and the pure-water supply line 63 at the above-determined flow rate and is supplied to the through-hole 61. Further, the pure water that has been supplied to the through-hole 61 is sucked by the drain pump device 78.

Since the steps 4 to 6 are the same as the steps 4 to 6 shown in FIG. 4, the repetitive descriptions thereof are omitted.

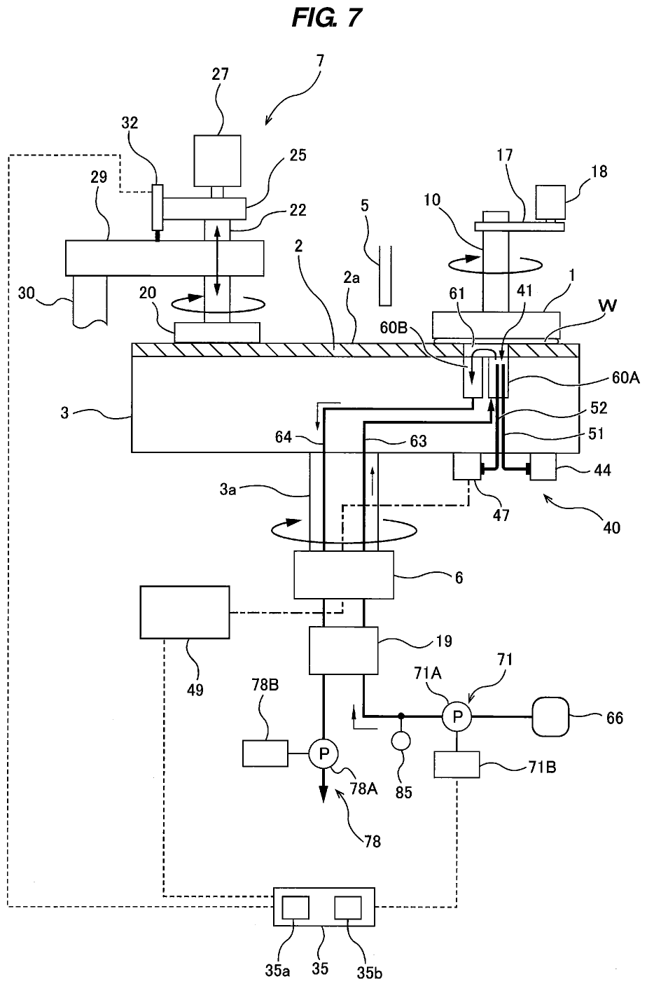

FIG. 7 is a schematic view showing another embodiment of the polishing apparatus. Configurations and operations of the present embodiment, which will not be particularly described, are the same as those of the embodiments described with reference to FIGS. 1 to 4, and therefore the repetitive descriptions thereof will be omitted. In this embodiment, the polishing apparatus includes feeding pump device 71 and pressure measuring device 85 which are coupled to the pure-water supply line 63. The feeding pump device 71 is a variable speed pump device, and serves as a pressure adjusting device for adjusting pressure of liquid flowing through the pure-water supply line 63. The feeding pump device 71 and the pressure measuring device 85 are located at the stationary side of the rotary joint 19 and are located outside the polishing table 3. The pressure measuring device 85 is arranged between the rotary joint 19 and the feeding pump device 71.

Since the configurations of the feeding pump device 71, which is a pressure adjusting device, are the same as those of the feeding pump device 71 shown in FIG. 1, the repetitive descriptions thereof will be omitted. The pressure of the pure water to be supplied to the through-hole 61, i.e., the pressure of the pure water flowing through the pure-water supply line 63, is measured by the pressure measuring device 85. The pressure of the pure water to be supplied to the through-hole 61 through the pure-water supply line 63 during polishing of the wafer W is uniquely defined by the rotation speed of the feeding pump device 71.

In the present embodiment, the pressure of the pure water to be supplied to the through-hole 61 is adjusted by the feeding pump device 71, which is a pressure adjusting device, based on the height of the polishing surface 2a. More specifically, as the height of the polishing surface 2a decreases, the pressure of the pure water to be supplied to the through-hole 61 is lowered by the feeding pump device 71. The pad-height measuring device 32 measures the height of the polishing surface 2a of the polishing pad 2 and transmits the measured value of the height of the polishing surface 2a to the operation controller 35.

The operation controller 35 includes memory 35a storing therein a program and a correlation data indicating a relationship between the height of the polishing surface 2a and the pressure of the pure water. The operation controller 35 further includes arithmetic device 35b configured to perform arithmetic operations according to instructions contained in the program to determine a pressure of the pure water corresponding to the measured value of the height of the polishing surface 2a and control the operation of the feeding pump device (pressure adjusting device) 71 so as to allow the pure water to flow through the pure-water supply line 63 at the determined pressure.

The purpose of supplying the pure water to the through-hole 61 during polishing of the wafer is to prevent the slurry, supplied to the polishing surface 2a, from entering the through-hole 61. When the pressure of the pure water is too high, the pure water can prevent the slurry from entering the through-hole 61, but the pure water overflows the through-hole 61 and dilutes the slurry. On the other hand, if the pressure of the pure water is too low, the through-hole 61 is not filled with the pure water, and the pure water cannot prevent the slurry from entering the through-hole 61. From this point of view, during polishing of the wafer, particularly when the through-hole 61 is covered with the wafer, the pressure of the pure water is such that the through-hole 61 is filled with the pure water and the pure water does not overflow onto the polishing surface 2a.

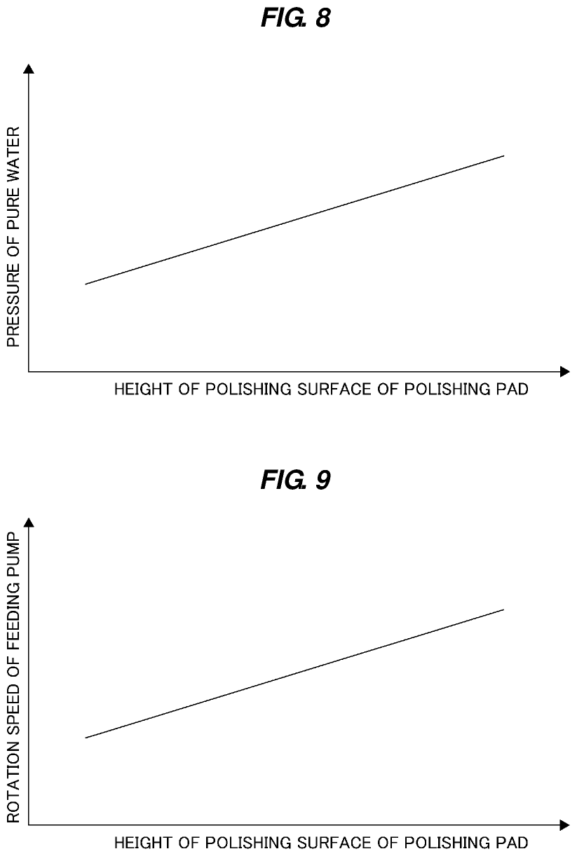

FIG. 8 is a diagram showing an example of correlation data indicating a relationship between the height of the polishing surface 2a and the pressure of the pure water. The correlation data indicates the relationship in which the pressure of the pure water decreases as the height of the polishing surface 2a decreases. The pressure of the pure water corresponding to each height of the polishing pad 2 is such that the pure water fills the through-hole 61 and does not overflow onto the polishing surface 2a. Such correlation data is obtained in advance by experiments. The correlation data may be a function of the pressure having the height of the polishing surface 2a as a variable as shown in FIG. 8, or a table showing a relationship between multiple numerical values of the height of the polishing surface 2a and multiple numerical values of the pressure of the pure water.

The pressure of the pure water included in the correlation data may be a physical quantity that directly indicates the pressure of the pure water, or may be a numerical value that indirectly indicates the pressure of the pure water. For example, the pressure of the pure water flowing through the pure-water supply line 63 to the through-hole 61 during polishing of the wafer W changes depending on the rotation speed of the feeding pump device 71. Therefore, the pressure of the pure water included in the correlation data may be represented by the rotation speed of the feeding pump device 71. Alternatively, the pressure of the pure water included in the correlation data may be another numerical value that indirectly indicates the pressure of the pure water.

FIG. 9 is a diagram showing an example of the correlation data indicating the relationship between the height of the polishing surface 2a and the rotation speed of the feeding pump device 71. In this embodiment, the correlation data shown in FIG. 9 is used. This correlation data is stored in the memory 35a of the operation controller 35. The correlation data shown in FIG. 9 is data in which the pressure of the pure water shown in FIG. 8 is replaced with the rotation speed of the feeding pump device 71.

The operation controller 35 receives the measured value of the height of the polishing surface 2a from the pad-height measuring device 32, and determines the rotation speed of the feeding pump device 71 (i.e., the pressure of the pure water) corresponding to the measured value of the height of the polishing surface 2a from the correlation data. Further, the operation controller 35 sets the operation of the feeding pump device 71 such that the pure water having the determined pressure flows through the pure-water supply line 63. More specifically, the operation controller 35 sends a command signal indicating the determined rotation speed to the inflow-side frequency variable device 71B, and the inflow-side frequency variable device 71B rotates the inflow-side pump 71A at the determined rotation speed. The pure water having the pressure corresponding to the height of the polishing surface 2a flows through the pure-water supply line 63 and flows into the through-hole 61. While the pure water is supplied to the through-hole 61, the drain pump device 78 is operated at a preset rotation speed. The pure water flows from the through-hole 61 to the second hole 60B, and further flows through the pure-water suction line 64 and is sucked by the drain pump device 78.

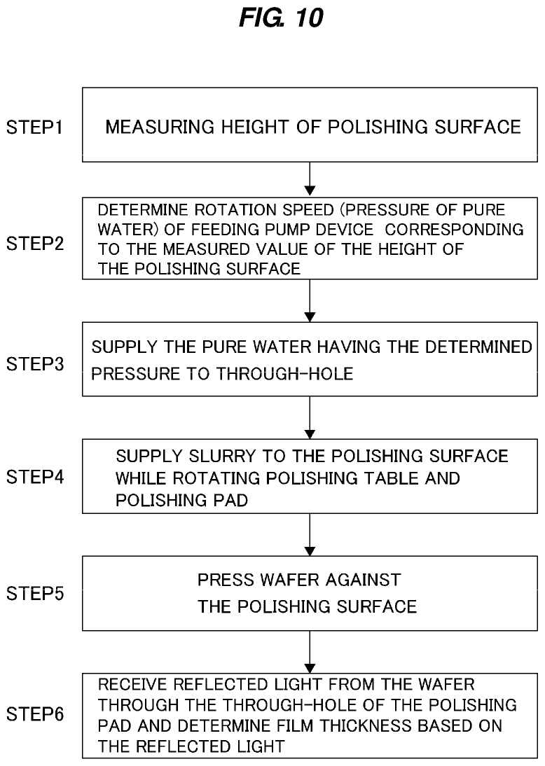

FIG. 10 is a flowchart illustrating the operation of the polishing apparatus shown in FIG. 7.

In step 1, the pad-height measuring device 32 measures the height of the polishing surface 2a while the dresser 20 dresses the polishing surface 2a of the polishing pad 2.

In step 2, the operation controller 35 determines from the correlation data the rotation speed of the feeding pump device 71 (i.e., the pressure of the pure water) corresponding to the measured value of the height of the polishing surface 2a. In step 3, the operation controller 35 instructs the feeding pump device 71 to operate at the rotation speed determined in the step 2 to thereby supply the pure water to the through-hole 61 through the pure-water supply line 63. Further, the pure water that has been supplied to the through-hole 61 is sucked by the drain pump device 78.

In step 4, the slurry is supplied from the slurry supply nozzle 5 to the polishing surface 2a while the polishing table 3 and the polishing pad 2 are rotated.

In step 5, the polishing head 1 presses the wafer W against the polishing surface 2a while the polishing head 1 rotates the wafer W. The surface of the wafer W is polished by the chemical action of the slurry and the mechanical action of the abrasive grains contained in the slurry. While the wafer W is pressed against the polishing surface 2a, the feeding pump device 71 operates at the rotation speed determined in the step 2.

In step 6, the optical film-thickness measuring system transmits the light to the surface of the wafer W on the polishing surface 2a through the through-hole 61, and receives the reflected light from the wafer W through the through-hole 61. During polishing of the wafer W, the optical film-thickness measuring system determines the film thickness of the wafer W based on the reflected light. The polishing end point of the wafer W is determined based on the film thickness of the wafer W.

According to the embodiment, the pressure of the pure water to be supplied to the through-hole 61 is changed based on the change in the thickness of the polishing pad 2. Such operation can prevent the pure water from overflowing the through-hole 61 of the polishing pad 2 during polishing of the wafer W, and can fill the through-hole 61 with the pure water. As a result, the slurry is prevented from entering the through-hole 61, and the optical film-thickness measuring system 40 can accurately measure the film thickness of the wafer W.

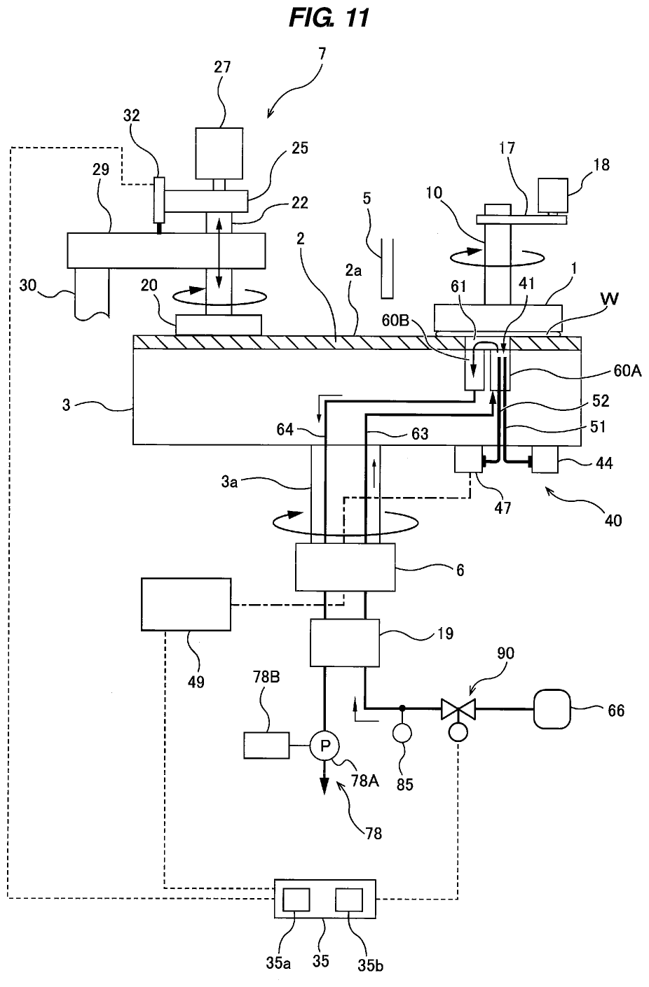

FIG. 11 is a schematic view showing another embodiment of the polishing apparatus. Configurations and operations of the present embodiment, which will not be particularly described, are the same as those of the embodiments described with reference to FIGS. 7 to 10, and therefore the repetitive descriptions thereof will be omitted. In the present embodiment, a pressure control valve 90 is provided, instead of the feeding pump device 71, as the pressure adjusting device. The arrangement of the pressure control valve 90 is the same as that of the feeding pump device 71 shown in FIG. 7. The configuration of this embodiment is suitable when the pressure of the pure water supplied from the pure-water supply source 66 is high to some extent.

A correlation data stored in the memory 35a is the correlation data shown in FIG. 8 indicating the relationship between the height of the polishing surface 2a and the pressure of the pure water. The arithmetic device 35b is configured to perform the arithmetic operations according to the instruction included in the program to determine the pressure of the pure water corresponding to the measured value of the height of the polishing surface 2a, and control the operation of the pressure control valve 90 so as to allow the pure water having the determined pressure to flow through the pure-water supply line 63.

More specifically, the operation controller 35 receives the measured value of the height of the polishing surface 2a from the pad-height measuring device 32, and determines the pressure of the pure water corresponding to the measured value of the height of the polishing surface 2a from the correlation data. Further, the operation controller 35 sets the operation of the pressure control valve 90 so that the pure water having the above-determined pressure flows through the pure-water supply line 63. More specifically, the operation controller 35 sends a command signal indicating the determined pressure to the pressure control valve 90, and the pressure control valve 90 operates according to the command signal. The pure water having the determined pressure flows through the pure-water supply line 63 and flows into the through-hole 61. While the pure water is supplied to the through-hole 61, the drain pump device 78 is operated at a preset rotation speed. The pure water flows from the through-hole 61 to the second hole 60B, and further flows through the pure-water suction line 64 and is sucked by the drain pump device 78.

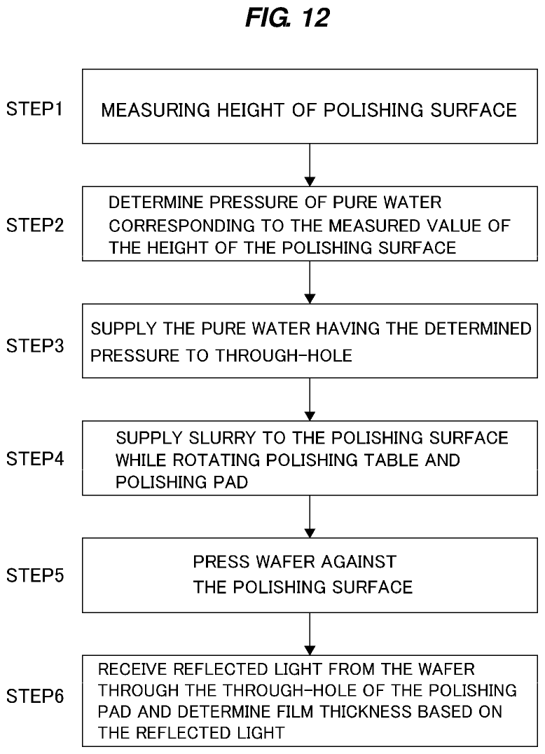

FIG. 12 is a flowchart illustrating the operation of the polishing apparatus shown in FIG. 11.

In step 1, the pad-height measuring device 32 measures the height of the polishing surface 2a while the dresser 20 dresses the polishing surface 2a of the polishing pad 2.

In step 2, the operation controller 35 determines from the correlation data the pressure of the pure water corresponding to the measured value of the height of the polishing surface 2a.

In step 3, the operation controller 35 instructs the pressure control valve 90 to allow the pure water having the pressure determined in the step 2 to flow. The pure water having the determined pressure flows through the pressure control valve 90 and the pure-water supply line 63 and is supplied to the through-hole 61. Further, the pure water that has been supplied to the through-hole 61 is sucked by the drain pump device 78.

Since steps 4 to 6 are the same as the steps 4 to 6 shown in FIG. 4, the repetitive descriptions thereof are omitted.

In each of the above-described embodiments, the drain pump device 78 is operated at a preset rotation speed regardless of the decrease in the height of the polishing surface 2a, while in one embodiment, the rotation speed of the drain pump device 78 may be lowered according to the decrease in the measured value of the height of the polishing surface 2a. The change in the rotation speed of the drain pump device 78 is achieved by changing the frequency of the voltage applied from the outflow-side frequency variable device 78B to the electric motor (not shown) of the outflow-side pump 78A.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a polishing apparatus and a polishing method for polishing a substrate while detecting a film thickness of the substrate by analyzing reflected light from the substrate on a polishing pad.

### REFERENCE SIGNS LIST

1 polishing head
2 polishing pad
3 polishing table
5 slurry supply nozzle
6 table motor
7 dressing unit
10 head shaft
17 coupling device
18 polishing-head motor
19 rotary joint
20 dresser
22 dresser shaft
25 support block
27 air cylinder
29 dresser arm
30 support shaft
32 pad-height measuring device
35 operation controller
35a memory
35b arithmetic device
40 optical film-thickness measuring system
41 optical sensor head
44 light source
47 spectrometer
49 data processor
51 light-emitting optical fiber cable
52 light-receiving optical fiber cable
60A first hole
60B second hole
61 through-hole
63 pure-water supply line
64 pure-water suction line
66 pure-water supply source
71 feeding pump device (flow-rate adjusting device)
71A inflow-side pump
71B inflow-side frequency variable device
73 flow-rate measuring device
78 drain pump device
78A outflow-side pump
78B outflow-side frequency variable device
80 flow-rate control valve
85 pressure measuring device
90 pressure control valve

1. A polishing apparatus for a substrate, comprising:
a polishing table configured to support a polishing pad, the polishing pad having a through-hole;
a polishing head configured to press the substrate against a polishing surface of the polishing pad;
a pad-height measuring device configured to measure a height of the polishing surface;
a pure-water supply line and a pure-water suction line coupled to the through-hole;
an optical film thickness measurement system configured to direct light to the substrate through the through-hole, receive reflected light from the substrate through the through-hole, and determine a film thickness of the substrate based on the reflected light;
a flow-rate adjusting device coupled to the pure-water supply line; and
an operation controller configured to control an operation of the flow-rate adjusting device,
the operation controller including:
a memory storing a program and correlation data indicating a relationship between the height of the polishing surface and flow rate of the pure water, and
an arithmetic device configured to perform an arithmetic operation according to an instruction included in the program to determine a flow rate of the pure water corresponding to a measured value of the height of the polishing surface, and control the operation of the flow-rate adjusting device such that the pure water flows through the pure-water supply line at the determined flow rate.

2. The polishing apparatus according to claim 1, wherein the correlation data indicates the relationship in which the flow rate of the pure water decreases as the height of the polishing surface decreases.

3. The polishing apparatus according to claim 1, wherein:
the flow-rate adjusting device comprises a feeding pump device;
the correlation data indicates a relationship between the height of the polishing surface and rotation speed of the feeding pump device; and
the arithmetic device is configured to perform the arithmetic operation according to the instruction included in the program to determine a rotation speed of the feeding pump device corresponding to the measured value of the height of the polishing surface, and set operation of the feeding pump device such that the feeding pump device rotates at the determined rotation speed.

4. The polishing apparatus according to claim 1, wherein:
the flow-rate adjusting device comprises a flow-rate control valve; and
the arithmetic device is configured to perform the arithmetic operation according to the instruction included in the program to determine a flow rate of the pure water corresponding to the measured value of the height of the polishing surface, and set operation of the flow-rate control valve such that the pure water flows through the pure-water supply line at the determined flow rate.

5. The polishing apparatus according to claim 1, further comprising:
an outflow-side pump coupled to the pure-water suction line; and
a frequency variable device configured to control a rotation speed of the outflow-side pump.

6. A polishing apparatus for a substrate, comprising:
a polishing table configured to support a polishing pad, the polishing pad having a through-hole;
a polishing head configured to press the substrate against a polishing surface of the polishing pad;
a pad-height measuring device configured to measure a height of the polishing surface;
a pure-water supply line and a pure-water suction line coupled to the through-hole;
an optical film thickness measurement system configured to direct light to the substrate through the through-hole, receive reflected light from the substrate through the through-hole, and determine a film thickness of the substrate based on the reflected light;
a pressure adjusting device coupled to the pure-water supply line; and
an operation controller configured to control an operation of the pressure adjusting device,
the operation controller including:
a memory storing a program and correlation data indicating a relationship between the height of the polishing surface and pressure of the pure water, and
an arithmetic device configured to perform an arithmetic operation according to an instruction included in the program to determine a pressure of the pure water corresponding to a measured value of the height of the polishing surface, and control the operation of the pressure adjusting device such that the pure water having the determined pressure flows through the pure-water supply line.

7. The polishing apparatus according to claim 6, wherein the correlation data indicates the relationship in which the pressure of the pure water decreases as the height of the polishing surface decreases.

8. The polishing apparatus according to claim 6, wherein:
the pressure adjusting device comprises a feeding pump device;
the correlation data indicates a relationship between the height of the polishing surface and rotation speed of the feeding pump device; and
the arithmetic device is configured to perform the arithmetic operation according to the instruction included in the program to determine a rotation speed of the feeding pump device corresponding to the measured value of the height of the polishing surface, and set operation of the feeding pump device such that the feeding pump device rotates at the determined rotation speed.

9. The polishing apparatus according to claim 6, wherein:
the pressure adjusting device comprises a pressure control valve; and
the arithmetic device is configured to perform the arithmetic operation according to the instruction included in the program to determine a pressure of the pure water corresponding to the measured value of the height of the polishing surface, and set operation of the pressure control valve such that the pure water having the determined pressure flows through the pure-water supply line.

10. The polishing apparatus according to claim 6, further comprising:
an outflow-side pump coupled to the pure-water suction line and;
a frequency variable device configured to control a rotation speed of the outflow-side pump.

11. A polishing method for a substrate, comprising:
measuring a height of a polishing surface of a polishing pad, the polishing pad having a through-hole;
determine, from correlation data, a flow rate of pure water corresponding to a measured value of the height of the polishing surface, the correlation data indicating a relationship between the height of the polishing surface and flow rate of the pure water;
pressing the substrate against the polishing surface of the polishing pad to polish the substrate while supplying slurry onto the polishing surface;
directing light from an optical film-thickness measuring system to the substrate through the through-hole and receiving reflected light from the substrate through the through-hole by the optical film-thickness measuring system, while supplying the pure water into the through-hole at the determined flow rate and sucking the pure water from the through-hole; and
determining a film thickness of the substrate based on the reflected light by the optical film-thickness measuring system.

12. The polishing method according to claim 11, wherein the correlation data indicates the relationship in which the flow rate of the pure water decreases as the height of the polishing surface decreases.

13. The polishing method according to claim 11, wherein the determined flow rate of the pure water is such that the through-hole is filled with the pure water and the pure water does not overflow onto the polishing surface.

14. A polishing method for a substrate, comprising:
measuring a height of a polishing surface of a polishing pad, the polishing pad having a through-hole;
determine, from correlation data, a pressure of pure water corresponding to a measured value of the height of the polishing surface, the correlation data indicating a relationship between the height of the polishing surface and pressure of the pure water;
pressing the substrate against the polishing surface of the polishing pad to polish the substrate while supplying slurry onto the polishing surface;
directing light from an optical film-thickness measuring system to the substrate through the through-hole and receiving reflected light from the substrate through the through-hole by the optical film-thickness measuring system, while supplying the pure water having the determined pressure into the through-hole and sucking the pure water from the through-hole; and
determining a film thickness of the substrate based on the reflected light by the optical film-thickness measuring system.

15. The polishing method according to claim 14, wherein the correlation data indicates the relationship in which the pressure of the pure water decreases as the height of the polishing surface decreases.

16. The polishing method according to claim 14, wherein the determined pressure of the pure water is such that the through-hole is filled with the pure water and the pure water does not overflow onto the polishing surface.
